(19) United States
(12) Patent Application Publication
(10) Pub. No.: US 2026/0006728 A1
(43) Pub. Date: Jan. 1, 2026

(54) CIRCUIT ASSEMBLY

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Koushi IGURA, Osaka (JP); Hiroki SHIMODA, Osaka (JP); Taiji YANAGIDA, Osaka (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 18/871,635

(22) PCT Filed: Jun. 1, 2023
(86) PCT No.: PCT/JP2023/020404

§ 371 Date: Aug. 8, 2025

(30) Foreign Application Priority Data
Jun. 10, 2022 (JP) 2022-094496

(51) Int. Cl. H05K 5/02; H02G 5/06

(52) U.S. Cl. CPC H05K 5/0217; H02G 5/06

(57) ABSTRACT

A circuit assembly that can reduce stress generated at an interface between a heat conducting member and a case is disclosed. A circuit assembly 10 includes: heat generating components 12, 14, a bus bar 18 connected to connector portions 16 of the heat generating components 12, 14, a case 20 that houses the heat generating components 12, 14 and the bus bar 18, and a heat conducting member 24 that is placed on a mounted surface 22 of the case 20, is in thermal contact with the case 20 and the bus bar 18 and is sandwiched therebetween. The case 20 includes a displacement restricting portion 118 that engages with a heat conductive member 24 and restricts displacement of the heat conducting member 24.

### TECHNICAL FIELD

The present disclosure relates to a circuit assembly including a heat-generating component.

### BACKGROUND ART

In the past, vehicles have been equipped with a circuit assembly including a heat-generating component, such as a relay. As one example, Patent Document 1 discloses a circuit assembly in which a first bus bar connected to an output terminal of a battery, a second bus bar connected to an input terminal of a load, and a relay connected between the first and second bus bars are housed in a case. In this circuit assembly, to dissipate the heat generated by the relay, which is a heat-generating component, to the outside, a structure is used where the bus bar connected to the relay is pressed against the case via a sheet-like heat conducting member so that heat generated by the relay is transferred to the case.

### CITATION LIST

### Patent Documents

Patent Document 1: JP 2018-93711A

### SUMMARY OF INVENTION

### Technical Problem

However, with the structure according to Patent Document 1, the heat conducting member, which is disposed via an adhesive or the like in a predetermined region of the case, is simply held in the predetermined region by being sandwiched between one case (a device cover) and another case (a battery case). This means that if an excessive impact or the like is applied or if a relative displacement occurs between the cases due to a difference in linear expansion coefficient between one case and the other case, distortion may occur at the interface between the heat conducting member and the case, which may produce a gap between the heat conducting member and the case and reduce the efficiency of heat transfer.

For this reason, a circuit assembly capable of reducing the stress produced at an interface between a heat conducting member and a case is disclosed.

### Solution to Problem

A circuit assembly according to an aspect of the present disclosure includes: a heat generating component; a bus bar connected to a connector portion of the heat generating component; a case for housing the heat generating component and the bus bar; and a heat conducting member that is mounted on a mounted surface of the case, is in thermal contact with the case and the bus bar, and is interposed between the case and the bus bar, wherein the case includes a displacement restricting portion that engages with the heat conducting member and restricts displacement of the heat conducting member.

### Advantageous Effects of Invention

According to an aspect of the present disclosure, it is possible to provide a circuit assembly capable of reducing the stress produced at an interface between a heat conducting member and a case.

### BRIEF DESCRIPTION OF DRAWINGS

FIG. 1 is a perspective view of a circuit assembly according to a first embodiment.

FIG. 2 is a plan view of the circuit assembly depicted in FIG. 1.

FIG. 3 is an enlarged longitudinal sectional view of a cross section taken along a line III-III in FIG. 2.

FIG. 4 is an exploded perspective view of the circuit assembly depicted in FIG. 1.

FIG. 5 is a perspective view from a bottom surface side of an upper case that constitutes the circuit assembly depicted in FIG. 1.

FIG. 6 is a perspective view of a lower case that constitutes the circuit assembly depicted in FIG. 1.

FIG. 7 is a longitudinal sectional view depicting a circuit assembly according to a second embodiment and corresponds to FIG. 3.

FIG. 8 is a perspective view from a bottom surface side of an upper case that constitutes the circuit assembly depicted in FIG. 7.

FIG. 9 is a perspective view of a lower case that constitutes the circuit assembly depicted in FIG. 7.

FIG. 10 is a longitudinal sectional view depicting a circuit assembly according to a third embodiment and depicts a cross section corresponding to a cross-section taken along a line X-X in FIG. 2.

FIG. 11 is a perspective view from a bottom surface side of an upper case that constitutes the circuit assembly depicted in FIG. 10.

FIG. 12 is a perspective view of a lower case that constitutes the circuit assembly depicted in FIG. 10.

### DESCRIPTION OF EMBODIMENTS

### Outline of Embodiments of the Present Disclosure

Several embodiments of the present disclosure will first be listed and described in outline.

A circuit assembly according to an aspect of the present disclosure includes: a heat generating component; a bus bar connected to a connector portion of the heat generating component; a case for housing the heat generating component and the bus bar; and a heat conducting member that is mounted on a mounted surface of the case, is in thermal contact with the case and the bus bar, and is interposed between the case and the bus bar, wherein the case includes a displacement restricting portion that engages with the heat conducting member and restricts displacement of the heat conducting member.

With the circuit assembly according to an aspect of the present disclosure, the case that houses the heat generating component and the bus bar that is connected to the connector portion of the heat generating component includes a displacement restricting portion that engages with the heat conducting member, which is in thermal contact with the case and the bus bar and is interposed between them. The displacement restricting portion can engage with the heat conducting member and restrict displacement of the heat conducting member. This means that displacement of the heat conducting member relative to the case is advantageously suppressed or prevented, so that stress produced at the interface between the case and the heat conducting member can be advantageously reduced or eliminated. As a result, the risk of gaps being produced at the interface between the case and the heat conducting member can be reduced, and the desired heat transferring performance of the circuit assembly for heat which is transferred from the connector portion of the heat generating component to the case via the bus bar and the heat conducting member, can be stably maintained. Note that it is sufficient for displacement of the heat conducting member relative to the case to be suppressed or prevented in at least one of the front-rear, the left-right, and the vertical directions in the embodiments described below.

The bus bar connected to the connector portion of the heat generating component may constitute a conductive path or may be used simply as a heat dissipating metal that is not electrically connected to other members.

It is preferable for the displacement restricting portion to include a protruding portion that protrudes from the mounted surface of the case, for the heat conducting member to include a first through hole through which the protruding portion is inserted, and for the bus bar to include a second through hole that is placed on the first through hole and through which the protruding portion is inserted and positioned. Since the protruding portion that protrudes from the mounted surface of the case is inserted through the first through hole of the heat conducting member, the stress produced at the interface between the case and the heat conducting member can be advantageously reduced. In addition, since the same protruding portion is also inserted through and positioned at the second through hole provided in the bus bar that is placed on the heat conducting member, even if for example the heat conducting member and the bus bar are held in one case and another case that have different linear expansion coefficients, transmission of a displacing force that acts on the heat conducting member via the bus bar can be suppressed, so that the stress produced at the interface between the case and the heat conducting member can be advantageously reduced.

It is preferable for the case to include a lower case, which includes the mounted surface, and an upper case that is assembled with the lower case with the heat conducting member and the bus bar interposed therebetween, for the upper case to include a locked portion, and for the protruding portion to include a locking portion that is provided on the lower case and fits together with and locks to the locked portion. Since the case includes the lower case, which includes the mounted surface, and the upper case, which is assembled so that the heat conducting member and the bus bar are sandwiched between the lower case and the upper case, and the protruding portion is formed using a locking portion which achieves locking engagement between the lower case and the upper case, the protruding portion can be provided efficiently. Furthermore, since the locking portion that constitutes the protruding portion is provided on the mounted surface on which the heat conducting member is placed, the engagement force of the lower case and the upper case can act directly on a part where the heat conducting member and the bus bar overlap each other, which can more advantageously suppress displacement of the heat conducting member relative to the case. As a result, even if the lower case and the upper case have different linear expansion coefficients, relative displacement between the two cases in the vicinity of the heat conducting member can be more effectively suppressed and stress produced at the interface between the case and the heat conducting member can be advantageously reduced.

Note that since the pressing force applied by the heat conducting member on the case due to the locking engagement between the upper case and the lower case can be adjusted by adjusting the locking allowance between the locking portion and the locked portion, by appropriately adjusting the locking allowance, the pressing force can be adjusted in keeping with the material, elastic properties, and the like of the heat conducting member.

It is preferable for the upper case to include a positioning rib that positions the bus bar, and for the bus bar to be positioned by engagement with the positioning rib, and for the locked portion of the upper case to be positioned with respect to the second through hole of the bus bar, the first through hole of the heat conducting member, and also the locking portion that has been passed through and positioned at the second through hole and the first through hole. By providing a positioning rib for the bus bar on the upper case, the locked portion of the upper case can be positioned relative to the second through hole of the bus bar, the first through hole of the heat conducting member, and also the locking portion of the lower case that has been inserted through such holes, which improves the ease of assembly.

It is preferable for the lower case and the upper case to respectively include a guide portion and a guided portion, which are disposed outward of the locking portion and the locked portion, respectively, and when assembling the upper case to the lower case, for the guided portion to be guided by the guide portion so that the locked portion of the upper case is positioned on the locking portion of the lower case. Since the lower case and the upper case are guided in advance by the guide portion and the guided portion, which are positioned outward of the locking portion and the locked portion, to position the locking portion and locked portion, the ease of assembling the lower case and the upper case can be further improved.

It is preferable for the case to include a lower case, which includes the mounted surface, and an upper case that is assembled with the lower case with the heat conducting member and the bus bar interposed therebetween, for the upper case to include a press-fitting hole, and for the protruding portion to be provided on the lower case and include a press-fitting protrusion that is press-fitted into the press-fitting hole. Since the case includes the lower case, which includes the mounted surface, and the upper case, which is assembled by sandwiching the heat conducting member and the bus bar between the lower case and the upper case, and the protruding portion is constructed of a press-fitting protrusion which enables the lower case and the upper case to be assembled by press-fitting, the protruding portion can be provided efficiently. Also, since the press-fitting protrusion that constitutes the protruding portion is provided on the mounted surface on which the heat conducting member is placed, the force when assembling the lower case and the upper case can act directly at a position where the heat conducting member and the bus bar overlap each other, which further advantageously suppresses displacement of the heat conducting member relative to the case.

It is preferable for the displacement restricting portion to include an elastic locking piece that protrudes from a peripheral edge of the mounted surface of the case, for the elastic locking piece to include a flexible piece, which is capable of elastic deformation in an outward direction for the heat conducting member, and a locking claw portion, which is provided at a protruding end portion of the flexible piece, and for the locking claw portion to engage with an edge portion of the bus bar that has been placed on the heat conducting member. By providing the elastic locking piece that protrudes from the peripheral edge of the mounted surface and having a locking claw of the elastic locking piece engage with the edge of the bus bar that has been placed on the heat conducting member, displacement of the heat conducting member relative to the case can be suppressed. As a result, it is possible to more effectively suppress displacement of the heat conducting member relative to the mounted surface and more effectively reduce stress produced at the interface between the heat conducting member and the case. In addition, since there is no need to provide a hole in the bus bar, the conduction resistance of the bus bar can be advantageously maintained when the bus bar is used as a conductive member.

It is preferable for the upper case to include a pressing portion that brings the bus bar into contact with the heat conducting member, and for the locked portion to be provided on the pressing portion. The upper case is provided with the pressing portion that brings the bus bar into contact with the heat conducting member, with the locked portion being provided on the pressing portion. This enables the fastening force of the locking structure of the upper and lower cases to be used to press the bus bar onto the heat conducting member and to contribute to both maintaining the efficiency of heat transfer and the ability to prevent displacement of the heat conducting member relative to the case.

### Detailed Description of Embodiments of the Present Disclosure

Preferred embodiments of a circuit assembly according to the present disclosure will now be described with reference to the drawings. Note that the present invention is not limited to these examples but is defined by the claims, and is intended to include all changes made within the meaning and scope equivalent to the claims.

### First Embodiment

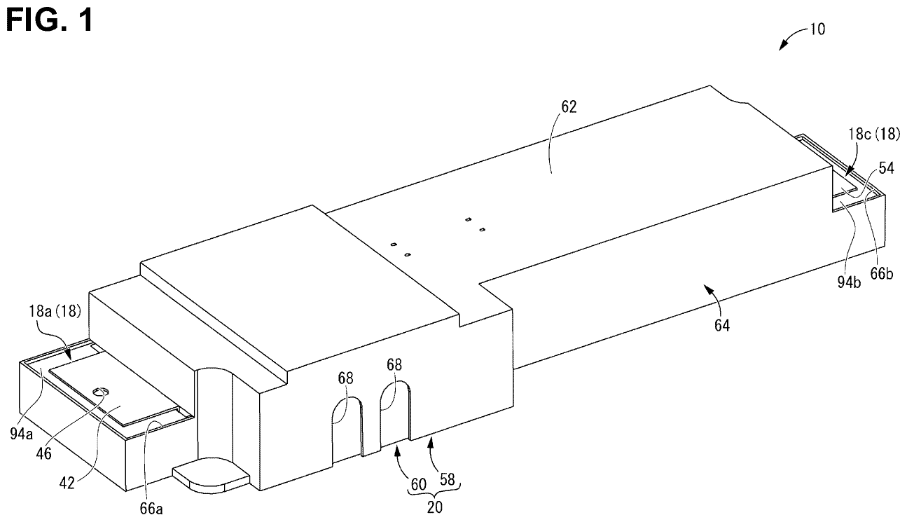

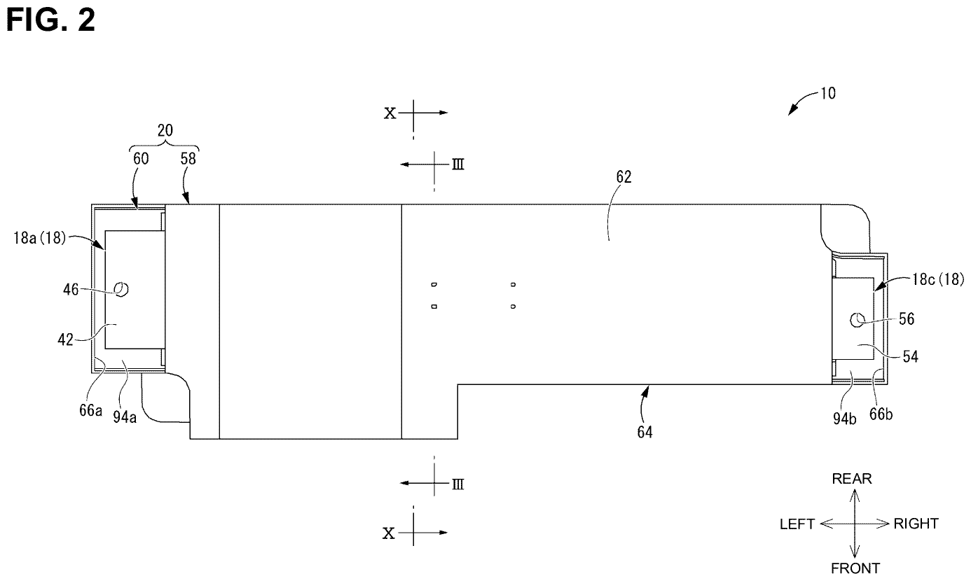

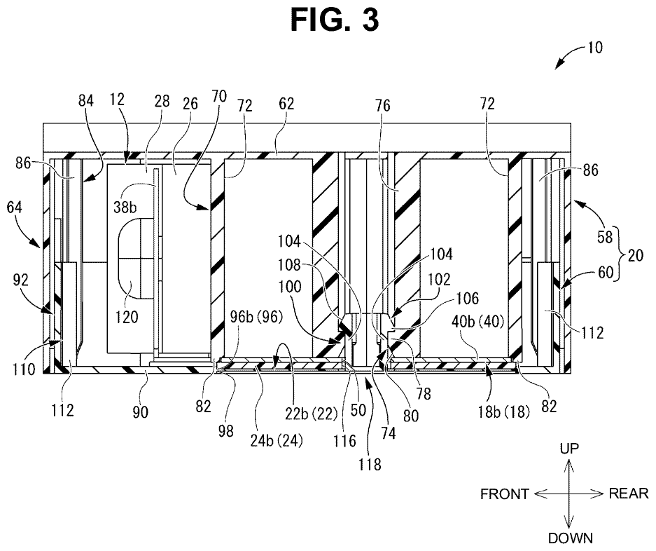

A first embodiment of the present disclosure will now be described with reference to FIGS. 1 to 6. A circuit assembly 10 according to the first embodiment is mounted in a vehicle, such as an electric vehicle or a hybrid vehicle (not illustrated), and supplies and controls power from a power source (not illustrated), such as a battery, to a load (also not illustrated), such as a motor. Although the circuit assembly 10 can be disposed in a freely chosen orientation, in the following description, the expression “upward” refers to upward in FIG. 3, “downward” refers to downward in FIG. 3, “the front” refers to downward in FIG. 2, “the rear” refers to upward in FIG. 2, “the left” refers to the left in FIG. 2, and “the right” refers to the right in FIG. 2. For a plurality of members that are the same, reference numerals may be assigned to only some of the members with reference numerals being omitted for the other members.

### Circuit Assembly 10

The circuit assembly 10 includes a relay 12 and a fuse 14 as heat-generating components that generate heat when a current flows, bus bars 18 that are connected to connector portions 16 of the heat-generating components (the relay 12 and the fuse 14), a case 20 that houses the heat generating components (the relay 12 and the fuse 14) and the bus bars 18, heat conducting sheets 24 (the first to third heat conducting sheets 24a to 24c described later) as heat conducting members that are placed on mounted surfaces 22 (the first to third mounted surfaces 22a to 22c described later) of the case 20 and are in thermal contact with and interposed between the case 20 and the bus bar 18.

### Heat-Generating Components (Relay 12 and Fuse 14)

The relay 12 has a relay body 26 in the form of a hollow cuboid. A pair of connector portions 16, 16 (that is, a first connector portion 16a and a second connector portion 16b) are provided on the front surface of the relay body 26 so as to be spaced apart from each other in the left-right direction. An insulating plate 28 that protrudes toward the front is provided between the first connector portion 16a and the second connector portion 16b. The relay body 26 is also provided with a plurality of leg portions 30 which protrude outward in the left-right direction. In the first embodiment, bolt insertion holes that extend through in the vertical direction are formed in the leg portions 30, with the relay 12 being fixed to an upper case 58, described later, that constitutes the case 20 by bolts that are inserted through these bolt insertion holes.

The fuse 14 is provided with a fuse body 32 that is substantially cuboid in shape. The fuse body 32 is provided with the connector portions 16, 16 (that is, a third connector portion 16c and a fourth connector portion 16d) that are made of metal and protrude on both sides in the left-right direction. Bolt insertion holes 34 that extend through in the vertical direction are formed in the third and fourth connector portions 16c and 16d, with the fuse 14 being fixed to an upper case 58, described later, that constitutes the case 20 by bolts 36 that are inserted through these bolt insertion holes 34.

### Bus Bars 18

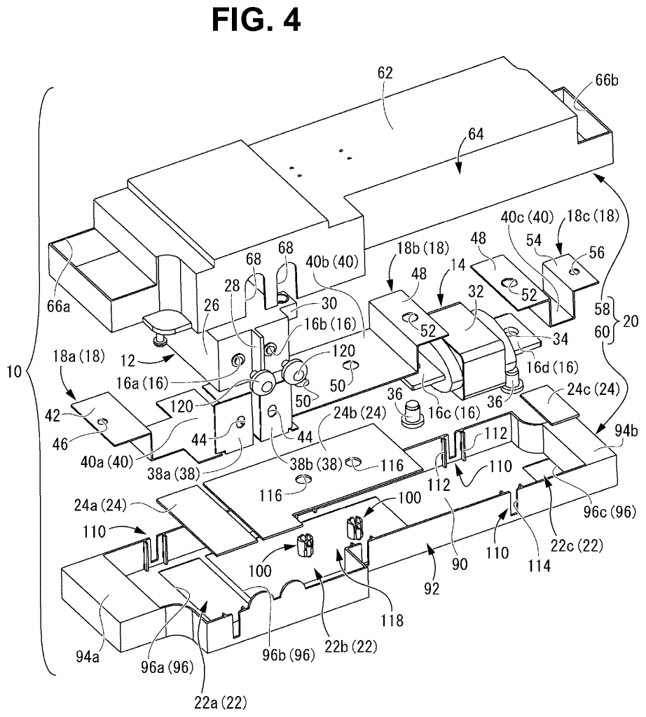

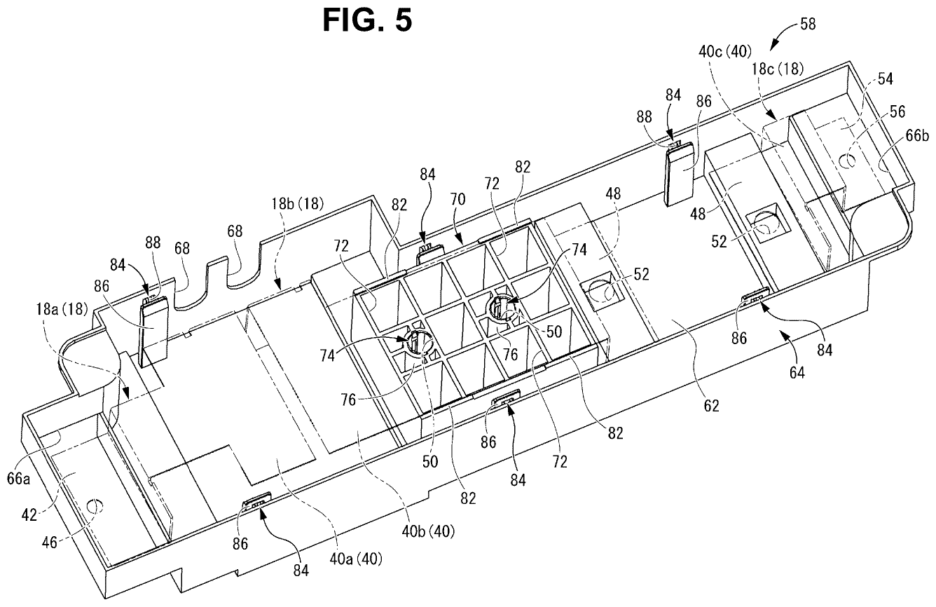

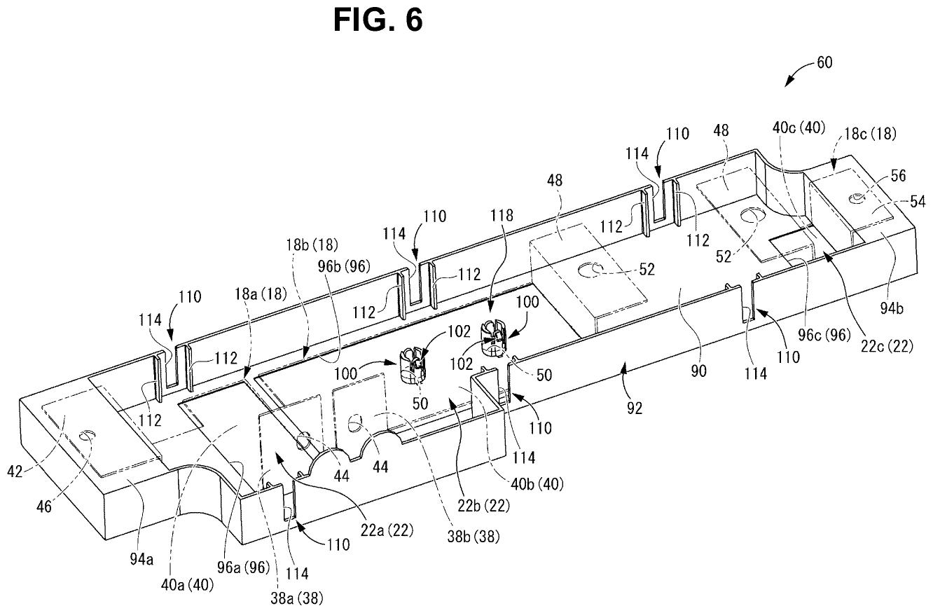

The bus bars 18 are formed by bending a metal plate material into predetermined shapes by press machining or the like. Although there are no particular limitations on the material of the bus bars 18, copper, copper alloy, aluminum, aluminum alloy, or the like is preferably used. As depicted in FIG. 4, in this first embodiment, three bus bars 18 are provided so as to be spaced apart from each other in the left-right direction, from the left, namely a first bus bar 18a, a second bus bar 18b, and a third bus bar 18c. Note that in FIGS. 5 and 6, the first to third bus bars 18a, 18b, and 18c that are fixed to the upper case 58 and the lower case 60, described later, are indicated by two-dot chain lines.

The first bus bar 18a as a whole extends in the left-right direction. A substantially rectangular relay connector portion 38 (or “first relay connector portion 38a”) which extends in the vertical direction is provided at the right end of the first bus bar 18a. A substantially rectangular heat transfer portion 40 (or “first heat transfer portion 40a”), which extends in the horizontal direction (a direction that is perpendicular to the vertical direction), extends to the rear from the lower end of the first relay connector portion 38a. The first bus bar 18a is also provided, at a left end thereof, with a left external connector portion 42 that is substantially rectangular and extends in the horizontal direction. The left external connector portion 42 is positioned higher than the first heat transfer portion 40a, and the left external connector portion 42 and the first heat transfer portion 40a are connected by a part that is bent into a crank shape in the middle in the left-right direction.

A bolt insertion hole 44 that passes through in the thickness direction (the front-rear direction) is formed in the first relay connector portion 38a. In the first embodiment, the bolt insertion hole 44 is elliptical in shape with the vertical direction as the major axis. By doing so, it is possible to adjust the vertical position of the first bus bar 18a relative to the relay 12 when, as described later, the relay 12 and the first bus bar 18a are bolted together. As a result, when assembling the circuit assembly 10, the first heat transfer portion 40a can be more reliably brought into thermal contact with the lower case 60, as described later, via a heat conducting sheet 24 (the first heat conducting sheet 24a). A bolt insertion hole 46 that passes through in the thickness direction (that is, the vertical direction), is also formed in the left external connector portion 42.

The second bus bar 18b as a whole extends in the left-right direction. A relay connector portion 38 (or “second relay connector portion 38b”), which is substantially rectangular and extends in the vertical direction, is provided at the left end of the second bus bar 18b, with a bolt insertion hole 44 that is elliptical in shape with the vertical direction as the major axis being formed in this second relay connector portion 38b. A heat transfer portion 40 (or “second heat transfer portion 40b”) that is substantially rectangular and extends in the horizontal direction is connected to the lower end of the second relay connector portion 38b. The second heat transfer portion 40b extends to the rear from the lower end of the second relay connector portion 38b and also extends in the left-right direction from the second relay connector portion 38b at the left end of the second bus bar 18b to a right part of the second bus bar 18b. A fuse connector portion 48, which is substantially rectangular and extends in the horizontal direction, is provided at the right end of the second bus bar 18b. The fuse connector portion 48 is positioned higher than the second heat transfer portion 40b, and the fuse connector portion 48 and the second heat transfer portion 40b are connected by a part that extends in the vertical direction.

In the first embodiment, circular through holes 50 that extend through in the thickness direction (that is, the vertical direction) are provided in substantially the middle in the front-rear direction of the second heat transfer portion 40b, which extends in the left-right direction. In this first embodiment in particular, a pair of through holes 50, 50 are provided, with this pair of through holes 50, 50 being spaced apart from each other in the left-right direction. As depicted in FIG. 3, the inner diameter of each of these through holes 50 is set to be substantially equal to or slightly smaller than a maximum outer diameter of a part, described later, of each protruding portion 100 of the lower case 60 where engagement claws 106 provided at an upper end part of the protruding portion 100 are formed, and is set to be approximately equal to or slightly larger than the outer diameter of the part of each protruding portion 100 where the engagement claws 106 are not formed.

By doing so, as described later, when the protruding portions 100 are inserted through the through holes 50, the engagement claws 106 (that is, the elastic pieces 104) elastically deform radially inward, which enables the protruding portions 100 to be inserted through the through holes 50. After the protruding portions 100 have been inserted through the through holes 50, the engagement claws 106 (the elastic pieces 104) are elastically restored, which can prevent the protruding portions 100 from coming out of the through holes 50. A bolt insertion hole 52 that passes through in the thickness direction (that is, the vertical direction) is formed in the fuse connector portion 48. That is, on the second bus bar 18b, the through holes 50 are provided relatively close to the bolt insertion holes 44 and 52.

The third bus bar 18c as a whole extends in the left-right direction. A fuse connector portion 48, which is substantially rectangular and extends in the horizontal direction, is provided at the left end of the third bus bar 18c, with a bolt insertion hole 52 that passes through in the thickness direction (that is, the vertical direction) being formed in this fuse connector portion 48. A right external connector portion 54, which is substantially rectangular and extends horizontally, is provided at the right end of the third bus bar 18c, with a bolt insertion hole 56 that extends through in the thickness direction (that is, the vertical direction) being formed in this right external connector portion 54.

The third bus bar 18c is provided with a substantially rectangular heat transfer portion 40 (the third heat transfer portion 40c) in the middle portion in the left-right direction. That is, the fuse connector portion 48 positioned at the left end of the third bus bar 18c and the right external connector portion 54 positioned at the right end are connected via the third heat transfer portion 40c. The third heat transfer portion 40c is positioned lower than the fuse connector portion 48 and the right external connector portion 54, and the third heat transfer portion 40c is connected to the fuse connector portion 48 and the right external connector portion 54 by parts that extend in the vertical direction.

### Case 20

The case 20 as a whole is box-shaped and as one example is made of synthetic resin. As depicted in FIG. 2, in the first embodiment, the case 20 is substantially rectangular and extends in the left-right direction when viewed from above. The case 20 is constituted by the upper case 58 that is positioned above and the lower case 60 that is positioned below. The upper case 58 and the lower case 60 can be assembled and disassembled in the vertical direction. Note that there are no particular limitations on the synthetic resin material that constitutes the upper case 58 and the lower case 60, and as one example it is possible to include a filler such as glass fiber. The material of the upper case 58 and the material of the lower case 60 may differ. It is especially preferable for the material of the lower case 60 to have favorable thermal conductivity, and as one example a nylon-based synthetic resin, such as polyamide 6 (PA6), may be used.

### Upper Case 58

The upper case 58 as a whole is substantially box-shaped and open downward and is provided with an upper bottom wall 62, which is substantially rectangular and extends in the left-right direction, and an upper peripheral wall 64, which protrudes downward from the outer peripheral edge of the upper bottom wall 62. Openings 66a, 66b, which are substantially rectangular and extend through in the vertical direction, are also formed at both ends in the left-right direction of the upper bottom wall 62. In addition, notches 68, which extend through in the thickness direction (the front-rear direction) are provided in a front part of the upper peripheral wall 64 at positions corresponding to the connector portions 16 (the first and second connector portions 16a, 16b) of the relay 12 that is fixed to the upper case 58. This pair of notches 68, 68 are spaced apart from each other in the left-right direction. By providing the notches 68, it is possible to fasten bolts 120 (described later) from the front through the notches 68 to the respective connector portions 16 (the first and second connector portions 16a, 16b) of the relay 12 that has been fixed to the upper case 58.

As depicted in FIGS. 3 and 5, the upper case 58 is provided with a pressing portion 70 that brings the bus bars 18 into contact with the heat conducting sheets 24. The pressing portion 70 as a whole is substantially cuboid in shape and is provided so as to protrude downward from the upper bottom wall 62 into an internal space of the upper case 58. In the first embodiment, the pressing portion 70 is formed integrally with the upper bottom wall 62 in the middle portion in the left-right direction of the upper bottom wall 62 with predetermined dimensions in the front-rear and left-right directions. In particular, in this first embodiment, the pressing portion 70 is formed with a front-rear dimension that is slightly larger than the front-rear dimension of a part of the second heat transfer portion 40b of the second bus bar 18b where the through holes 50 are formed.

The pressing portion 70 also has a predetermined dimension in the vertical direction, and as described later, in a state where the bus bars 18 (specifically, the second bus bar 18b) and the heat conducting sheet 24 (the second heat conducting sheet 24b) have been placed on each other at a lower end of the pressing portion 70, the pressing portion 70 is placed on a bottom wall 90, described later, of the lower case 60 via the bus bars 18 (specifically, the second bus bar 18b) and the heat conducting sheets 24 (the second heat conducting sheet 24b). In other words, the upper case 58 and the lower case 60 are assembled with the heat conducting sheets 24 (the second heat conducting sheet 24b) and the bus bars 18 (the second bus bar 18b) sandwiched in the vertical direction between the pressing portion 70 and the bottom wall 90.

The pressing portion 70 includes a plurality of hollows 72, which are substantially rectangular and open downward, and this plurality of hollows 72 are aligned in the front-rear and left right directions. This means that when the upper case 58 is viewed from below, the pressing portion 70 is formed in substantially a grid pattern. The pressing portion 70 is also formed with locked portions 74 into which locking portions 102 (described later) provided on the lower case 60 is fitted and locked. In more detail, the locked portions 74 are provided at lower end parts of cylindrical portions 76 that protrude downward from the upper bottom wall 62. In the first embodiment, the cylindrical portions 76 are provided inside hollows 72 in the middle portion in the front-rear direction of the pressing portion 70, with a pair of cylindrical portions 76, 76 being provided so as to be spaced apart from each other in the left-right direction. That is, on the upper case 58, a pair of locked portions 74, 74 are provided so as to be spaced apart from each other in the left-right direction.

In more detail, at the lower end part of each cylindrical portion 76, engaged claws 78, which protrude inward, are provided on both sides in the front-rear direction to form a locked portion 74 at the lower end part of each cylindrical portion 76. The lower end surfaces of the engaged claws 78 that face each other in the front-rear direction are formed as inclined surfaces 80, and each of these inclined surfaces 80 is inclined in a direction so that the distance between the facing surfaces in the front-rear direction gradually increases toward the bottom.

Positioning ribs 82 for positioning a bus bar 18 (the second bus bar 18b) are provided at both ends in the front-rear direction of the pressing portion 70. The positioning ribs 82 protrude downward from both ends in the front-rear direction of the pressing portion 70. In the first embodiment, positioning ribs 82, 82 with a predetermined dimension in the left-right direction are provided at both ends in the left-right direction and both ends in the front-rear direction of the pressing portion 70 so as to be spaced apart from each other in the left-right direction. The separation distance in the front-rear direction between the positioning ribs 82, 82 that face each other in the front-rear direction is substantially equal to or slightly larger than the front-rear dimension of the part of the second heat transfer portion 40b of the second bus bar 18b where the through holes 50 are formed. By doing so, when the second bus bar 18b is placed on the pressing portion 70, the second bus bar 18b is positioned between the positioning ribs 82, 82 that are separated in the front-rear direction.

In addition, the inner circumferential surface of the upper peripheral wall 64 of the upper case 58 is provided with guided portions 84 for guiding guide portions 110 (described later) provided on the lower case 60 when the upper case 58 and the lower case 60 are assembled. In the first embodiment, a plurality of guided portions 84 are provided so as to be spaced apart from each other in the left-right direction at parts on both sides in the front-rear direction of the inner circumference surface of the upper peripheral wall 64. That is, on the upper case 58, the guided portions 84 are provided outward of the locked portions 74.

In more detail, each guided portion 84 includes a guided portion body 86 that is substantially cuboid in shape and is formed with predetermined dimensions in the left-right and front-rear directions. Each guided portion body 86 extends in the vertical direction in which the upper case 58 and the lower case 60 are assembled, with each guided portion body 86 protruding downward from the upper bottom wall 62. The vertical dimension of each guided portion body 86 is substantially equal to the vertical dimension of the upper peripheral wall 64, so that the lower ends of the guided portion bodies 86 and the lower end of the upper peripheral wall 64 are at substantially the same position in the vertical direction.

Each of the guided portion bodies 86 is positioned a predetermined distance inward (that is, inward in the front-rear direction in the first embodiment) of the upper peripheral wall 64, and the upper peripheral wall 64 and each guided portion body 86 are coupled by a linking portion 88. The linking portions 88 extend in the vertical direction with a vertical dimension that is smaller than the guided portion bodies 86. The linking portions 88 also have a left-right dimension that is smaller than the guided portion bodies 86, with each linking portion 88 connecting the upper peripheral wall 64 and a guided portion body 86 at the middle portion in the left-right direction of that guided portion body 86.

### Lower Case 60

As depicted in FIG. 6, the lower case 60 as a whole is substantially box-shaped and open upward and is provided with a bottom wall 90, which is substantially rectangular and extends in the left-right direction, and a lower peripheral wall 92, which protrudes upward from the outer edge of the bottom wall 90. Support portions 94a, 94b that have a substantially rectangular block shape and support the left external connector portion 42 of the first bus bar 18a and the right external connector portion 54 of the third bus bar 18c, respectively, during assembly of the circuit assembly 10, are provided at both ends in the left-right direction of the lower case 60. As a result, during assembly of the circuit assembly 10, the left and right external connector portions 42, 54 supported on the support portions 94a, 94b are exposed upward through the two openings 66a, 66b in the upper case 58.

Note that nuts (not illustrated) are provided in a substantially embedded state in these support portions 94a, 94b, and by placing the left and right external connector portions 42, 54 and terminals (not illustrated) provided at the ends of external electric wires on both support portions 94a, 94b, and inserting bolts through the bolt insertion holes 46, 56 and fastening the bolts to the nuts, the first and third bus bars 18a, 18c and the external electric wires are brought into an electrically conductive state.

An upper housing concave portion 96, which is substantially rectangular and open upward, is provided on the upper surface of the bottom wall 90 at a position corresponding to the heat transfer portions 40 of the bus bars 18. Since three bus bars (the first to third bus bars 18a to 18c) are provided in the first embodiment, first to third upper housing concave portions 96a to 96c that are spaced apart from each other in the left-right direction are provided on the upper surface of the bottom wall 90 at positions corresponding to the first to third heat transfer portions 40a to 40c of the first to third bus bars 18a to 18c. Also, as described later, since heat conducting sheets 24 (that is, first to third heat conducting sheets 24a to 24c) are placed on these first to third upper housing concave portions 96a to 96c, the bottom surfaces of the first to third upper housing concave portions 96a to 96c serve as mounted surfaces 22 (the first to third mounted surfaces 22a to 22c). Note that the first to third upper housing concave portions 96a to 96c are not essential, and heat conducting members (as examples, the first to third heat conducting sheets 24a to 24c) may be mounted on the upper surface of the bottom wall. In this case, the mounted surfaces may be constituted by the upper surface of the bottom wall.

Also, as depicted in FIG. 3, lower housing concave portions 98, which are substantially rectangular and open downward, are provided in the lower surface of the bottom wall 90 at positions corresponding to the first to third upper housing concave portions 96a to 96c. Note that although in the first embodiment, three lower housing concave portions 98 are provided spaced apart from each other in the left-right direction on the lower surface of the bottom wall 90 corresponding to the first to third upper housing concave portions 96a to 96c, FIG. 3 depicts only the lower housing concave portion 98 that corresponds to the second upper housing concave portion 96b. By providing these first to third upper housing concave portions 96a to 96c and the lower housing concave portions 98 in the bottom wall 90, the bottom wall 90 is thinner at the positions where the first to third upper housing concave portions 96a to 96c and the lower housing concave portions 98 are formed, than at other parts of the bottom wall 90.

A heat conducting member (or “heat conducting sheet”, not illustrated), which is similar to the first to third heat conducting sheets 24a to 24c mounted on the first to third upper housing concave portions 96a to 96c, is housed in and fixed to each of these lower housing concave portions 98. Since the bottom wall 90 is in thermal contact with a heat dissipating body (not illustrated) such as a vehicle body panel or a battery pack housing, via the heat conducting members (or “heat conducting sheets”) housed in the lower housing concave portions 98, heat generated at the relay 12 and/or the fuse 14 will be dissipated through the heat dissipating body.

In this configuration, the mounted surfaces 22 of the lower case 60 are provided with protruding portions 100 that protrudes upward. In the first embodiment, a pair of protruding portions 100, 100 that protrude upward from the second mounted surface 22b are provided at positions in the middle in both the left-right and front-rear directions of the lower case 60, with this pair of protrusions 100, 100 being spaced apart from each other in the left-right direction. In the particular example in this first embodiment, each protruding portion 100 includes a locking portion 102 that fits together with and locks to a locked portion 74 of the upper case 58.

In more detail, each protruding portion 100 has a substantially cylindrical shape that can be inserted into a cylindrical portion 76 on the upper case 58. A peripheral wall of each cylindrical shape has notches that are spaced apart at a plurality of locations in the circumferential direction. By doing so, elastic pieces 104 that can elastically deform in the radial direction of each protruding portion 100 are provided on both sides in the front-rear direction of each substantially cylindrical protruding portion 100. An engagement claw 106 that protrudes outward in the front-rear direction is provided at the upper end of each of these elastic pieces 104, with the locking portion 102 mentioned above of each protruding portion 100 being configured to include the elastic pieces 104 that include these engagement claws 106.

In other words, in this first embodiment, for each protruding portion 100, the elastic pieces 104 that include the engagement claws 106 are provided facing each other in the front-rear direction. The upper end surfaces of the engagement claws 106 are formed as inclined surfaces 108, with each inclined surface 108 being inclined in a direction so that the length by which each engagement claw 106 protrudes outward in the front-rear direction gradually increases toward the bottom.

The guide portions 110 are provided on the lower peripheral wall 92 of the lower case 60 at positions corresponding to the guided portions 84 on the upper case 58. In the first embodiment, a plurality of guide portions 110 are provided so as to be spaced apart from each other in the left-right direction at portions on both sides in the front-rear direction of the lower peripheral wall 92. That is, on the lower case 60, the guide portions 110 are provided outward of the locking portions 102.

In more detail, as depicted in FIGS. 4 and 6, each guide portion 110 is provided with a pair of guide wall portions 112, 112 that protrude inward (inward in the front-rear direction in the first embodiment) from the inner circumferential surface of the lower peripheral wall 92. Each of these guide wall portions 112, 112 extends in the vertical direction, and at each guide portion 110, the pair of guide wall portions 112, 112 are spaced apart from each other by a spacing in the left-right direction that is approximately equal to or slightly larger than the dimension in the left-right direction of the guided portion bodies 86 on the upper case 58. At each guide portion 110, a notched window 114, which is open upward and passes through the lower peripheral wall 92 in the front-rear direction, is provided in the middle in the left right direction between the pair of the guide wall portions 112, 112. Each notched window 114 is formed with a dimension in the vertical direction that does not reach the entire length in the vertical direction of the lower peripheral wall 92. The width dimension (in this first embodiment, the dimension in the left-right direction) of each notched window 114 is substantially equal to or slightly larger than the left-right dimension of each linking portion 88 on the upper case 58.

Since the guided portions 84 on the upper case 58 and the guide portions 110 on the lower case 60 are shaped as described above, when the upper case 58 and the lower case 60 are assembled, each guided portion body 86 is inserted into a gap in the left right direction between a pair of guide portions 112, 112 and each linking portion 88 is inserted into a notched window 114. By doing so, when the upper case 58 and the lower case 60 are assembled, the guide portions 110 are guided in the vertical direction relative to the guided portions 84.

In particular, by inserting each guided portion body 86 into a pair of guide wall portions 112, 112 in substantially a press-fitted state and inserting each linking portion 88 into each cutout window 114 also in substantially a press-fitted state, it is possible to assemble the upper case 58 and the lower case 60 in a state where the upper case 58 and the lower case 60 are fixed to each other. In other words, the guide portions 110 and the guided portions 84 may constitute a fixing mechanism for the upper case 58 and the lower case 60. Note that a fixing mechanism for the upper case 58 and the lower case 60 may be provided separately from the fixing mechanism using the guide portions 110 and the guided portions 84 or in addition to the fixing mechanism using the guide portions 110 and the guided portions 84. As one example, the locking portions 102 and the locked portions 74 fitting together in a locked state may be used as a fixing mechanism for the upper case 58 and the lower case 60.

### Heat Conducting Members (Heat Conducting Sheets 24)

When assembling the circuit assembly 10, the heat conducting sheets 24, which are sheet-like heat conducting members, are provided between the heat transfer portions 40 of the bus bars 18 and the bottom wall 90 of the lower case 60. In the first embodiment, the first to third heat conducting sheets 24a to 24c are housed in the first to third upper housing concave portions 96a to 96c in the bottom wall 90 of the lower case 60 at positions corresponding to the first to third heat transfer portions 40a to 40c of the first to third bus bars 18a to 18c. As a result, when the circuit assembly 10 is assembled, the first to third heat transfer portions 40a to 40c are brought into thermal contact with the bottom wall 90 via the first to third heat conducting sheets 24a to 24c. Note that the first to third heat conducting sheets 24a to 24c may be fixed to the lower surfaces of the first to third heat transfer portions 40a to 40c, may be fixed to the first to third mounted surfaces 22a to 22c of the first to third upper housing concave portions 96a to 96c, or may be fixed to neither. Also, as described earlier, a heat conducting member (not illustrated) is housed in each lower housing concave portion 98 in the bottom wall 90 of the lower case 60 and sandwiched in the vertical direction between the bottom wall 90 and the heat dissipating body.

The first to third heat conducting sheets 24a to 24c are sheets that are flat in the vertical direction and are made of a synthetic resin with higher thermal conductivity than air. In more detail, silicone-based resin, non-silicone acrylic resin, ceramic resin, or the like can be used. One specific example of a material is thermally conductive silicone rubber. The first to third heat conducting sheets 24a to 24c are flexible and elastic and are capable of elastically deformation so that the thickness dimension can change in response to a force applied in the vertical direction. Note that although sheet-shaped heat conducting members (for example, the first to third heat conducting sheets 24a to 24c) are used as the heat conducting members provided on both the upper and lower surfaces of the bottom wall 90 of the lower case 60 in this first embodiment, the heat conducting members are not limited to this form and heat conducting members of any freely-chosen shape can be used. As examples, the heat conducting members may be a heat dissipating gap filler made of a silicone-based resin, or thermal grease.

Although the synthetic resin that constitutes the case 20 (the upper case 58 and the lower case 60) and the synthetic resin material that constitutes the heat conducting members (the first to third heat conducting sheets 24a to 24c) are not limited to particular materials, as one example, when the lower case 60 is made of a nylon-based synthetic resin (as one example, PA6) and the first to third heat conducting sheets 24a to 24c are made of a silicone-based synthetic resin, since such lower case 60 and first to third heat conducting sheets 24a to 24c will be susceptible to peeling, the effects of the present disclosure will be more evident when such materials are used.

In particular, the first to third heat conducting sheets 24a to 24c are preferably sandwiched in the vertical direction in a compressed state between the first to third heat transfer portions 40a to 40c and the bottom wall 90 of the lower case 60. By being compressed, the first to third heat conducting sheets 24a to 24c can come into highly intimate contact with the first to third heat transfer portions 40a to 40c and the bottom wall 90 of the lower case 60. By doing so, it is possible for the first to third heat conducting sheets 24a to 24c to efficiently transfer heat from the first to third heat transfer portions 40a to 40c to the lower case 60. In the same way, each heat conducting member provided on the lower surface of the bottom wall 90 of the lower case 60 is preferably sandwiched in a compressed state in the vertical direction between the bottom wall 90 and the heat dissipating body. By doing so, it is possible for the heat conducting member to come into highly intimate contact with the bottom wall 90 and the heat dissipating body, which makes it possible to efficiently transfer heat from the lower case 60 to the heat dissipating body.

Here, the heat conducting sheets 24 are provided with through holes 116 through which the protruding portions 100 provided on the lower case 60 are inserted. Since a pair of protruding portions 100, 100 are provided on the second mounted surface 22b of the lower case 60 in this first embodiment, a pair of through holes 116, 116 are provided in the second heat conducting sheet 24b placed on the second mounted surface 22b. These through holes 116 are provided in substantially the middle portion in the front-rear direction of the second heat conducting sheet 24b and are spaced apart from each other in the left-right direction.

As depicted in FIG. 3, the inner diameter of each through hole 116 is substantially equal to the inner diameter of each through hole 50 provided in the second bus bar 18b. In other words, the inner diameter of each through hole 116 is substantially equal to or slightly smaller than the maximum outer diameter of an upper end part of each protruding portion 100 on the lower case 60 where the engagement claws 106 are formed, and is substantially equal to or slightly larger than the outer diameter of the parts of the protruding portions 100 where the engagement claws 106 are not formed.

By doing so, when the circuit assembly 10 is assembled, the protruding portions 100 on the lower case 60 are inserted through the through holes 116 in the second heat conducting sheet 24b, which restricts displacement of the second heat conducting sheet 24b relative to the lower case 60. Accordingly, in the first embodiment, a displacement restricting portion 118 that engages with the heat conducting sheets 24 and restricts displacement of the heat conducting sheets 24 is provided on the case 20 and is configured to include the protruding portions 100.

### Assembly Process of Circuit Assembly 10

Next, a specific example of an assembly process of the circuit assembly 10 will be described. Note that the assembly process of the circuit assembly 10 is not limited to the description given below.

First, the upper case 58, the lower case 60, the relay 12, the fuse 14, the first to third bus bars 18a to 18c, the bolts 36, the first to third heat conducting sheets 24a to 24c and the like are prepared. The relay 12 is placed on the upper bottom wall 62 of the upper case 58 which has been turned upside down, and the relay 12 is bolted to the upper case 58 using bolts inserted through the leg portions 30.

After this, the first and second bus bars 18a, 18b are placed on top of the relay 12, and the first and second connector portions 16a, 16b of the relay 12 and the bolt insertion holes 44 of the first and second bus bars 18a, 18b are aligned in the front-rear direction. When the second bus bar 18b is placed on the relay 12, the second heat transfer portion 40b of the second bus bar 18b is placed from above on the pressing portion 70 of the upper case 58, and the second bus bar 18b is positioned in the front-rear direction relative to the upper case 58 by the positioning ribs 82 provided on the pressing portion 70.

Next, bolts 120 are inserted from the front through the first and second connector portions 16a, 16b and the bolt insertion holes 44 and are fastened. By doing so, the relay 12 and the first and second bus bars 18a, 18b are fixed. When the second bus bar 18b is fixed to the relay 12 (the upper case 58) in this way, the inner holes of the cylindrical portions 76 in the pressing portion 70 and the through holes 50 in the second bus bar 18b are aligned so as to communicate with each other in the vertical direction.

Next, the third bus bar 18c is placed on the upper bottom wall 62 of the upper case 58, and the fuse 14 is placed on the second and third bus bars 18b, 18c so that the third and fourth connector portions 16c, 16d of the fuse 14 are placed on the fuse connector portions 48 of the second and third bus bars 18b, 18c. By doing so, the bolt insertion holes 52 of the respective fuse connector portions 48 are aligned with the bolt insertion holes 34 of the third and fourth connector portions 16c, 16d. The bolts 36 are then inserted through the bolt insertion holes 34, 52 and fastened. By doing so, in addition to the relay 12 and the first and second bus bars 18a, 18b, the fuse 14 and the third bus bar 18c are fixed to the upper case 58.

The upper case 58 is then turned upside down and placed facing the lower case 60 from above. Note that the heat conducting sheets 24 (the first to third heat conducting sheets 24a to 24c) are placed and fixed in advance via adhesive or the like to the mounted surfaces 22 (the first to third mounted surfaces 22a to 22c), which are the bottom surfaces of the first to third upper housing concave portions 96a to 96c of the lower case 60. By doing so, the protruding portions 100 of the lower case 60 are inserted through and engage with the through holes 116 in the second heat conducting sheet 24b. The guided portions 84 of the upper case 58 are inserted into the guide portions 110 of the lower case 60. By doing so, the inner holes of the cylindrical portions 76 and the through holes 50 that communicate with each other on the upper case 58 side and the protruding portions 100 that extend through the through holes 116 of the second heat conducting sheet 24b on the lower case 60 side are positioned facing each other in the vertical direction. In other words, the locked portions 74 provided on the cylindrical portions 76 and the locking portions 102 provided on the protruding portions 100 are positioned facing each other in the vertical direction.

The guide portions 110 are guided along the guided portions 84, which brings the upper case 58 and the lower case 60 closer together in the vertical direction. By doing so, the inclined surfaces 80 provided on each locked portion 74 and the inclined surfaces 108 provided on the locking portions 102 come into contact with each other in the vertical direction, and the elastic pieces 104 of the locking portions 102 elastically deform inward in the radial direction. This enables the protruding portions 100 to be inserted into the cylindrical portions 76, the through holes 50, and the through holes 116. Due to the engagement claws 106 of the locking portions 102 passing over the engaged claws 78 of the locked portions 74, the elastic pieces 104 are elastically restored, and the engagement claws 106 engages with the engaged claws 78. By doing so, the guided portions 84 are inserted into the guide portions 110 in a substantially press-fitted state and the locking portions 102 and the locked portions 74 are fixed together in a locked state, thereby fixing the upper case 58 and the lower case 60 to each other. As a result, the circuit assembly 10 is completed. In the complete state of the circuit assembly 10, the second bus bar 18b and the second heat conducting sheet 24b are placed on each other in the vertical direction, and the protruding portions 100 are inserted and positioned through the through holes 50 and the through holes 116 overlapped with each other.

The circuit assembly 10 that has been assembled in this way is placed on a heat dissipating body, such as a vehicle body panel or the case of a battery pack (not illustrated) and fixed with bolts or the like. By doing so, as one example, a heat conducting member (not illustrated) provided on the lower surface of the bottom wall 90 of the lower case 60 can be compressed in the vertical direction between the lower case 60 and the heat dissipating body. Heat that has been generated due to current flowing through the relay 12 and/or the fuse 14 is transmitted via the first to third heat transfer portions 40a to 40c of the first to third bus bars 18a to 18c, the first to third heat conducting sheets 24a to 24c, the bottom wall 90 of the lower case 60, and a heat conducting member (not illustrated) provided on the lower surface of the bottom wall 90 that have been stacked in the vertical direction and then dissipated from the heat dissipating body (not illustrated).

In the circuit assembly 10 according to the first embodiment, the lower case 60 that constitutes the case 20 is provided with the displacement restricting portion 118 that engages with the second heat conducting sheet 24b and restricts displacement of the second heat conducting sheet 24b. As a result, even when the case 20 expands or contracts through exposure to a high temperature environment, suffers a significant external impact, or the like, problems such as the production of gaps between the lower case 60 and the second heat conducting sheet 24b are suppressed, which means that the desired heat dissipating effect can be stably achieved. In particular, if the lower case 60 is made of a material that has favorable thermal conductivity relative to the upper case 58, the lower case 60 and the upper case 58 will be susceptible to becoming relatively displaced in a high-temperature environment due to the difference in linear expansion coefficients. In this case as well, the displacement restricting portion 118 will advantageously reduce the stress produced at the interface between the lower case 60 and the second heat conducting sheet 24b, making it possible for the circuit assembly 10 to maintain the desired heat dissipating effect.

In more detail, in the first embodiment, the displacement restricting portion 118 is configured to include the protruding portions 100 on the lower case 60, with the protruding portions 100 (that is, the locking portions 102) and the cylindrical portions 76 (that is, the locked portions 74) on the upper case 58 fitting together in a locked state. This prevents relative displacement between the upper case 58 and the lower case 60 in any of the front-rear, left-right, and vertical directions. This means that displacement of the second heat conducting sheet 24b sandwiched between the upper case 58 and the lower case 60 relative to the case 20 (the upper case 58 and the lower case 60) is suppressed in either of the front-rear and left-right directions (that is, shear directions), and the vertical direction (that is, the tensile direction), which enables the desired heat dissipating effect to be achieved.

The displacement restricting portion 118 includes the protruding portions 100 that protrude upward from the second mounted surface 22b of the lower case 60, and the protruding portions 100 are inserted through the through holes 50 provided in the second bus bar 18b and the through holes 116 provided in the second heat conducting sheet 24b. In this way, by using a structure in which the protruding portions 100 are inserted through the through holes 116 in the second heat conducting sheet 24b, it is possible to stably achieve an effect of restricting displacement of the second heat conducting sheet 24b relative to the lower case 60. Also, in the first embodiment, the through holes 50 (that is, the locked portions 74 and the locking portions 102) are provided in the second bus bar 18b relatively close to the bolt fastening points (that is, the bolt insertion holes 44, 52) where external forces tend to act. By doing so, the second bus bar 18b is prevented from deforming so as to cause rotation at the bolt fastening points due to impacts, differences in linear expansion coefficients, or the like. As a result, displacement of the second heat conducting sheet 24b sandwiched between the second bus bar 18b and the lower case 60 relative to the case 20 is also prevented. Note that the through holes in the bus bar (that is, the locking structure formed by the locked portions and the locking portions) may be provided at two locations that are separated from the rotation axes at the bolt fastening points (that is, the bolt insertion holes) in the bus bar and may be opposite to each other with the rotation axes in between. By doing so, it is possible to more effectively prevent rotational displacement of the bus bar relative to the case.

In particular, the case 20 is composed of an upper case 58 and a lower case 60, and the upper case 58 and the lower case 60 include the locked portions 74 and the locking portions 102 which fit together in a locked state. By doing so, even if an external force is applied to the upper case 58 and the lower case 60 in a direction that is opposite to the assembly direction and separates the upper case 58 and the lower case 60 in the vertical direction, relative displacement between the second bus bar 18b on the upper case 58 side and the lower case 60 is suppressed, and detachment of the second heat conducting sheet 24b sandwiched between the second bus bar 18b and the lower case 60 from the second bus bar 18b and the lower case 60 is prevented.

The upper case 58 is provided with the positioning ribs 82 at the pressing portion 70 that positions the second bus bar 18b. By doing so, it is possible to quickly align the second bus bar 18b with the upper case 58 when assembling the second bus bar 18b, to which the second heat conducting sheet 24b has been fixed, to the upper case 58. After the second heat conducting sheet 24b and the second bus bar 18b have been assembled to the upper case 58, displacement between the inner holes of the cylindrical portions 76 and the through holes 50 and the through holes 116 is effectively prevented, which means that insertion of the protruding portions 100 into the cylindrical portions 76, the through holes 50, and the through holes 116 can be stably achieved.

In particular, the upper case 58 is provided with the guided portions 84 and the lower case 60 is provided with the guide portions 110, and when the upper case 58 and the lower case 60 are assembled, the locking portions 102 and the locked portions 74 are positioned relative to each other in the vertical direction in a state where the guide portions 110 have been inserted into the guided portions 84. By doing so, the upper case 58 and the lower case 60 are brought closer to each other while maintaining a state where the guide portions 110 are inserted into the guided portions 84 and the locking portions 102 are caused to engage with the locked portions 74, which means that stable engagement can be realized between the locking portions 102 and the locked portions 74.

The upper case 58 includes the pressing portion 70, and the second bus bar 18b and the second heat conducting sheet 24b are sandwiched between the pressing portion 70 and the lower case 60. The pressing portion 70 is provided with the locked portions 74, which engage with the locking portions 102 of the lower case 60. That is, the second bus bar 18b and the second heat conducting sheet 24b are sandwiched in the vertical direction between the upper case 58 and the lower case 60 near the locking portions 102 and the locked portions 74 that lock the upper case 58 and the lower case 60. This means that the production of gaps between the second heat conducting sheet 24b and the lower case 60 due to vertical displacement causing separation between the upper case 58 and the lower case 60 can be effectively prevented.

### Second Embodiment

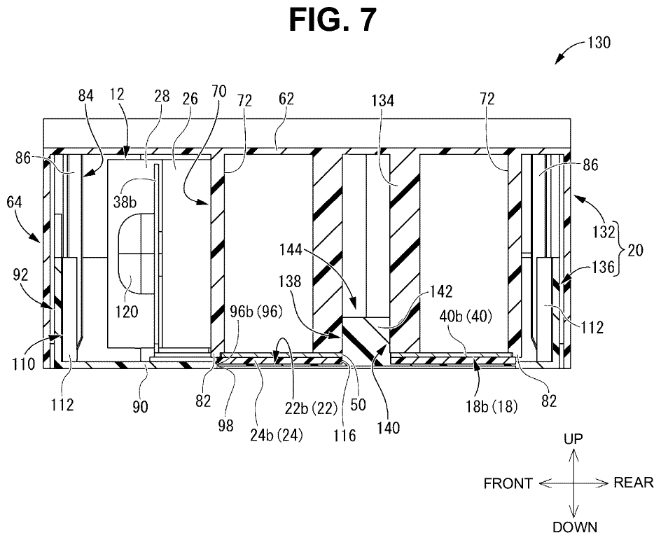

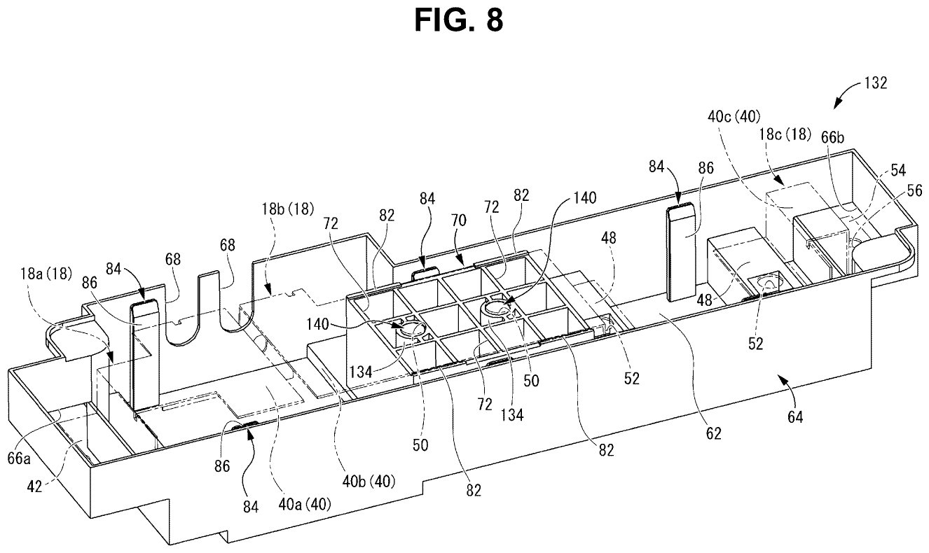

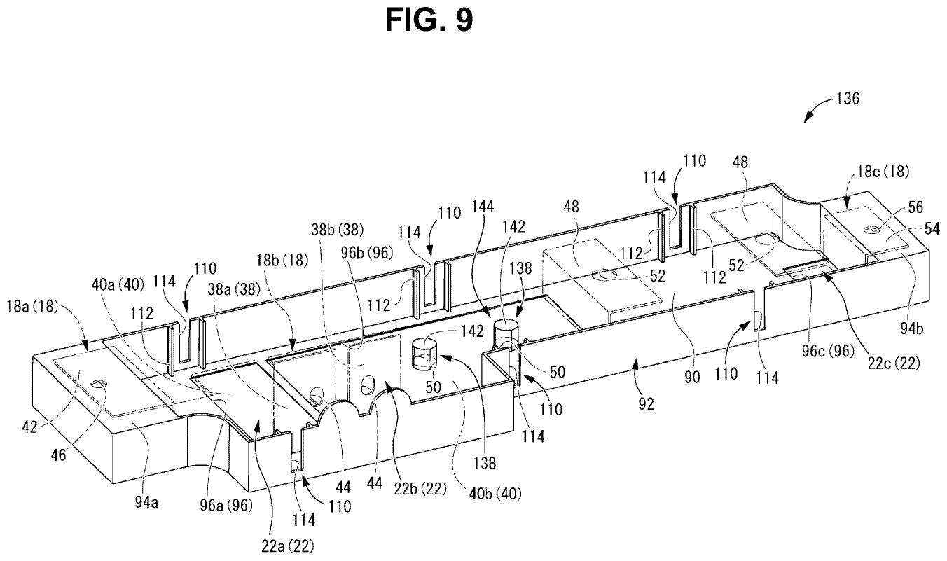

A second embodiment of the present disclosure is described below with reference to FIGS. 7 to 9. Although the circuit assembly 130 according to the second embodiment has the same fundamental structure as the circuit assembly 10 according to the first embodiment, the structures of tubular portions 134 provided on an upper case 132 and protruding portions 138 provided on a lower case 136 are different. Accordingly, in the following description, differences from the circuit assembly 10 according to the first embodiment will be explained, and detailed description is omitted for components and parts that are substantially the same as those in the first embodiment, which have been assigned the same reference numerals as the first embodiment in the drawings.

### Upper Case 132

Similarly to the upper case 58 according to the first embodiment, the upper case 132 according to the second embodiment is provided with the pressing portion 70 that protrudes downward from the middle portion in the left-right direction of the upper bottom wall 62. As in the first embodiment, the pressing portion 70 is provided with a plurality of hollows 72, with tubular portions 134 being provided inside the hollows 72 in the middle in the front-rear direction of the pressing portion 70. In this second embodiment also, a pair of the tubular portions 134, 134 are provided, with this pair of tubular portions 134, 134 being spaced apart in the left-right direction.

Here, although each cylindrical portion 76 is provided with engaged claws 78 that protrude inward to construct locked portions 74 in the first embodiment, each tubular portion 134 in this second embodiment has an inner diameter that is substantially constant over its entire length in the vertical direction. As described later, since the protruding portions 138 of the lower case 136 are press-fitted into inner holes in the tubular portions 134, in this second embodiment, the inner holes of the tubular portions 134 act as press-fitting holes 140.

### Lower Case 136

In the lower case 136 according to the second embodiment, similarly to the lower case 60 according to the first embodiment, protruding portions 138 that protrude upward are provided in the middle in the front-rear direction of the second mounted surface 22b. In the second embodiment as well, a pair of the protruding portions 138, 138 are provided, with this pair of protruding portions 138, 138 being spaced apart from each other in the left-right direction.

Here, although the elastic pieces 104 and the engagement claws 106 are provided on the protruding portions 100 according to the first embodiment to construct the locking portions 102, the protruding portions 138 according to the second embodiment have an outer diameter that is substantially constant over their entire length in the vertical direction. The outer diameter of each protruding portion 138 is substantially equal to or slightly larger than the inner diameter of each tubular portion 134 (that is, each press-fitting hole 140) on the upper case 132, so that when the upper case 132 and the lower case 136 are assembled, the protruding portions 138 are press-fitted into the press-fitting holes 140. That is, in the second embodiment, each protruding portion 138 includes a press-fitting protrusion 142.

Accordingly, in the second embodiment, the upper case 132 and the lower case 136 are fixed together by a press-fitting structure where the press-fitting protrusions 142 are pressed into the press-fitting holes 140 (and, as necessary, a press-fitting structure where the guided portions 84 are pressed into the guide portions 110). When doing so, the protruding portions 138 are inserted into and engage with the through holes 116 in the second heat conducting sheet 24b in advance, which restricts relative displacement between the lower case 136 and the second heat conducting sheet 24b. As a result, in the second embodiment, a displacement restricting portion 144 that includes the protruding portions 138 and restricts displacement of the second heat conducting sheet 24b is constructed.

In this way, since the circuit assembly 130 according to the second embodiment differs from the circuit assembly 10 according to the first embodiment in only the fixing structure of the upper case 132 and the lower case 136, the circuit assembly 130 according to the second embodiment can achieve the same effects as the circuit assembly 10 according to the first embodiment. In addition, in the second embodiment, the press-fitting holes 140 are provided in the pressing portion 70 and the press-fitting protrusions 142 on the lower case 136 are press-fitted into such press-fitting holes 140. As a result, in this second embodiment as well, the second bus bar 18b and the second heat conducting sheet 24b are sandwiched between the upper case 132 and the lower case 136 in the vertical direction near the press-fitting holes 140 and the press-fitting protrusions 142 that fix the upper case 132 and the lower case 136. This means that the production of gaps between the second heat conducting sheet 24b and the lower case 136 due to vertical displacement that separates the upper case 132 and the lower case 136 can be effectively prevented.

### Third Embodiment

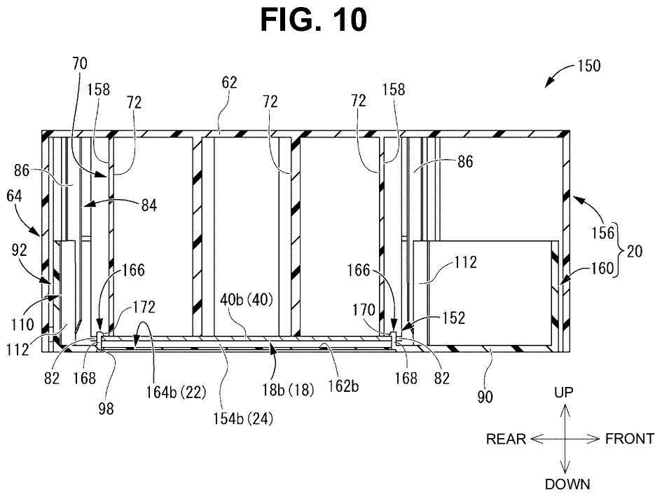

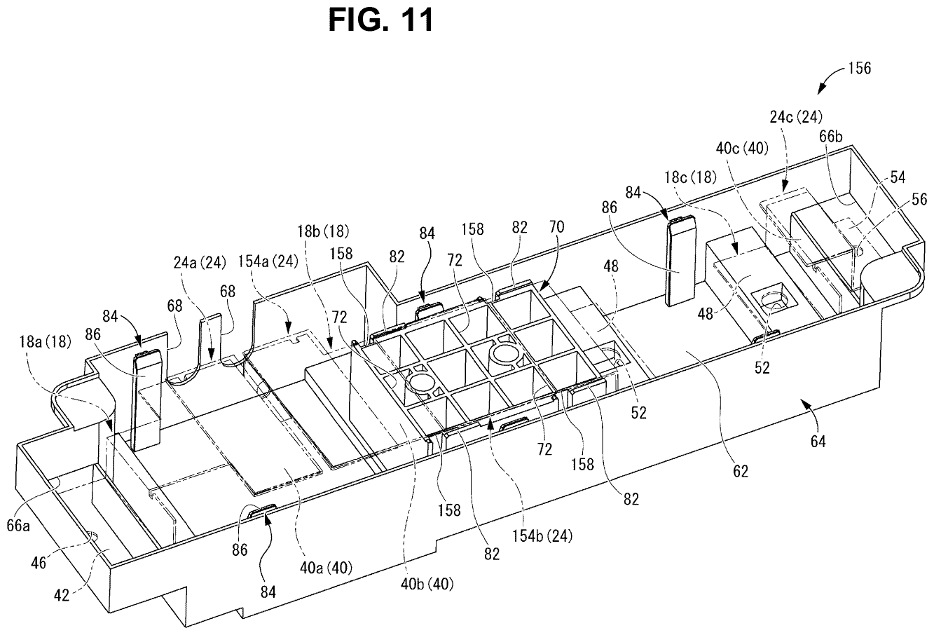

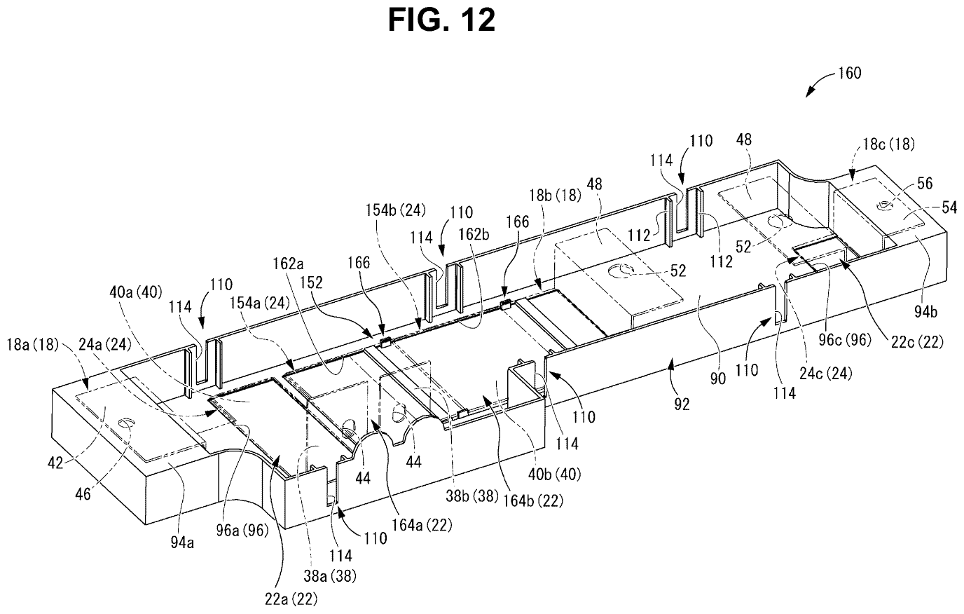

A third embodiment of the present disclosure will now be described with reference to FIG. 10 to FIG. 12. A circuit assembly 150 according to the third embodiment has the same fundamental structure as the circuit assembly 10 according to the first embodiment and the circuit assembly 130 according to the second embodiment but differs to the first and second embodiments in the structure of a displacement restricting portion 152. Accordingly, in the following description, differences from the first and second embodiments will be explained, and detailed description is omitted for components and parts that are substantially the same as those in the first and second embodiments, which have been assigned the same reference numerals as the first and second embodiments in the drawings. Note that in this third embodiment, similarly to the first and second embodiments, three bus bars 18 (the first to third bus bars 18a to 18c) are provided, and the second heat conducting sheet 24b that is placed on the second bus bar 18b is divided into two in the left-right direction so that a left second heat conducting sheet 154a and a right second heat conducting sheet 154b are provided. In FIGS. 11 and 12, in addition to the first to third bus bars 18a to 18c, the heat conducting sheets 24 (that is, the first and third heat conducting sheets 24a and 24c and the left and right second heat conducting sheets 154a, 154b) are indicated by chain double-dashed lines.

### Upper Case 156

Similarly to the upper case 58 according to the first embodiment, the upper case 156 according to the third embodiment is provided with the pressing portion 70 that protrudes downward from the middle portion in the left-right direction of the upper bottom wall 62. In this third embodiment, insertion channels 158 that outwardly open in the front-rear direction and extend in the vertical direction are provided on both sides in the front-rear direction of the outer circumferential surface of the pressing portion 70. In particular, in this third embodiment, the insertion channels 158 are provided at two locations that are spaced apart in the left-right direction on both sides in the front-rear direction of the pressing portion 70, meaning that a total of four insertion channels 158 are provided on the pressing portion 70.

Each insertion channel 158 is substantially rectangular in cross section and has a predetermined width dimension (the dimension in the left right direction) and depth dimension (the dimension in the front-rear direction). The depth dimension of each insertion channel 158 is greater than the width dimension (the dimension in the front-rear direction) of each positioning rib 82 provided at both ends in the front-rear direction of the pressing portion 70, which means that the bottom surface of each insertion channel 158 is positioned further inward in the front-rear direction than each positioning rib 82. As a result, when the second bus bar 18b is placed on the pressing portion 70, the lower opening of each insertion channel 158 becomes partially covered by both ends in the front-rear direction of the second bus bar 18b. In other words, when the second bus bar 18b is placed on the pressing portion 70, both ends in the front-rear direction of the second bus bar 18b protrude outward in the front-rear direction from the bottom surface of each insertion channel 158.

Note that as described above, in the third embodiment, the second heat conducting sheet 24b is divided in the left-right direction so that the left second heat conducting sheet 154a and the right second heat conducting sheet 154b are provided so as to be spaced apart from each other in the left-right direction. Here, the left second heat conducting sheet 154a is placed on the left part of the second bus bar 18b (the portion located to the left of the pressing portion 70 and below the relay 12). The right second heat conducting sheet 154b is placed on a part of the second bus bar 18b that corresponds to the space in the left-right direction between the insertion channels 158, 158 that are spaced apart from each other in the left-right direction. In other words, when assembling the circuit assembly 150, the left and right second heat conducting sheets 154a, 154b are provided in positions that are offset from the insertion channels 158 in the left-right direction.

### Lower Case 160

In this third embodiment, since the second heat conducting sheet 24b is divided in the left-right direction into the left and right second heat conducting sheets 154a, 154b, at the bottom wall 90 of the lower case 160, the second upper housing concave portion 96b that houses the second heat conducting sheet 24b is also divided in the left-right direction to produce a left second housing concave portion 162a and a right second housing concave portion 162b. That is, the left second heat conducting sheet 154a is housed in the left second housing concave portion 162a and the right second heat conducting sheet 154b is housed in the right second housing concave portion 162b. In other words, the bottom surfaces of the left second housing concave portion 162a and the right second housing concave portion 162b respectively form a left second mounted surface 164a and a right second mounted surface 164b.

Elastic locking pieces 166, which protrude upward, are provided on the peripheral edge of the right second mounted surface 164b at positions corresponding to the insertion channels 158 of the upper case 156. That is, the elastic locking pieces 166 are provided at two locations that are spaced apart from each other in the left right direction on both sides in the front-rear direction of the right second mounted surface 164b, which means that a total of four elastic locking pieces 166 are provided on the lower case 160. Note that as described earlier, since the right second heat conducting sheet 154b is provided in the space in the left-right direction between the insertion channels 158 that are spaced apart from each other in the left-right direction, at the right second housing concave portion 162b (the right second mounted surface 164b), the right second heat conducting sheet 154b is housed in a space in the left-right direction between the elastic locking pieces 166 that are spaced apart from each other in the left-right direction.

The elastic locking pieces 166 each have a flexible piece 168 that protrudes upward from the bottom wall 90 of the lower case 160 and is capable of elastic deformation toward both sides in the front-rear direction that form the outer periphery of the right second heat conducting sheet 154b, and a locking claw portion 170 that is provided at a protruding end (the upper end) of the flexible piece 168 and protrudes inward in the front-rear direction. The upper end surface of each locking claw portion 170 is formed as an inclined surface 172 that gradually inclines inward in the left-right direction toward the bottom.

When assembling the upper case 156 and the lower case 160 constructed as described above, the upper case 156 to which the various members have been fixed is disposed facing the lower case 160 from above. The upper case 156 and the lower case 160 are then brought closer to each other in the vertical direction by the guiding action of the guide portions 110 and the guided portions 84. As a result, the insertion channels 158 of the upper case 156 and the elastic locking pieces 166 of the lower case 160 face each other in the vertical direction, and the inclined surfaces 172 of the elastic locking pieces 166 are brought into contact with both ends in the front-rear direction of the second bus bar 18b that protrudes to cover the lower openings of the insertion channels 158. By then bringing the upper case 156 and the lower case 160 closer together in the vertical direction, the flexible pieces 168 of the elastic locking pieces 166 elastically deform outward in the front-rear direction. These elastic locking pieces 166 are elastically restored when the locking claw portions 170 pass over the second bus bar 18b, so that the locking claw portions 170 engage with both ends in the front-rear direction of the second bus bar 18b. As a result, the upper case 156 and the lower case 160 are fixed together by a locking mechanism composed of the elastic locking pieces 166 (the locking claw portions 170) (and, as necessary, a press-fitting structure composed of the guided portions 84 pressed into the guide portions 110), thereby completing the circuit assembly 150.

In the third embodiment, the locking claw portions 170 engage with the edges of the second bus bar 18b that has been placed on the right second heat conducting sheet 154b. That is, the elastic locking pieces 166 provided on the lower case 160 engage with the second bus bar 18b that has been fixed to the upper case 156, and the right second heat conducting sheet 154b becomes sandwiched in the vertical direction between the second bus bar 18b and the bottom wall 90 of the lower case 160. In this way, each elastic locking piece 166 engages with the second bus bar 18b, which restricts displacement of the right second heat conducting sheet 154b that is sandwiched between the second bus bar 18b and the bottom wall 90. In this third embodiment, the displacement restricting portion 152 includes these elastic locking pieces 166.

The circuit assembly 150 according to the third embodiment also includes the displacement restricting portion 152 that restricts the displacement of the right second heat conducting sheet 154b relative to the lower case 160, and therefore can achieve the same effect as the circuit assembly 150 according to the first embodiment. In particular, in the third embodiment, the elastic locking pieces 166 that construct the displacement restricting portion 152 are not inserted through the second bus bar 18b as in the first and second embodiments and instead engage with both ends in the front-rear direction of the second bus bar 18b. For this reason, there is no need to provide through holes in the second bus bar 18b for inserting the displacement restricting portion 152 (that is, the elastic locking pieces 166), which avoids any deterioration in electrical conductivity.

### Other Embodiments

The technology described in this specification is not limited to the embodiments described in the above description and depicted in the drawings. As examples, the following embodiments are also included in the technical scope of the technology described in this specification.
(1) Although a configuration where the bus bars 18 for conducting electricity (the first to third bus bars 18a to 18c) are provided with the heat transfer portions 40 (the first to third heat transfer portions 40a to 40c), and bus bars for conducting electricity and for transferring heat are used as the bus bars 18 in the above embodiment, bus bars for conducting electricity and bus bars for transferring heat may be separately used. In this case, a bus bar for conducting electricity and a bus bar for transferring heat may be fastened together and fixed with a bolt to a connector portion of a heat generating component (as examples, a relay or a fuse). When a bus bar for conducting electricity and a bus bar for transferring heat are provided separately, it is sufficient for the heat transferring bus bar, which together with the lower case sandwiches a heat conducting member (as one example, a heat transferring sheet), to be provided with through holes as in the first and second embodiments, or to be engaged by elastic locking pieces as in the third embodiment, and no particular structure is required for the bus bar that constitutes electricity.
(2) Although the guided portions 84 of the upper case 58, 132, or 156 are inserted into the guide portions 110 of the lower case 60, 136, or 160 in a substantially press-fitted state and contribute to the fixing of the upper case 58, 132, or 156 and the lower case 60, 136, or 160 in the embodiments described above, the present disclosure is not limited to this configuration. The upper case and the lower case may be fixed by at least one of the following structures: locking portions and locked portions fitting together in a locked state as in the first embodiment; a press-fitting structure where press-fitting protrusions are pressed into press-fitting holes as in the second embodiment; and a structure where elastic locking pieces provided on the lower case engage with a bus bar fixed to the upper case as in the third embodiment.

In other words, the guide portions and the guided portions do not need to have a function of fixing the upper case and the lower case together and may simply have a function of guiding the upper case and the lower case in a direction toward each other when the upper case and the lower case are assembled. A locking mechanism or the like, which fixes the upper case and the lower case together, may be provided on the upper peripheral wall of the upper case and the lower peripheral wall of the lower case separate from the guide portions and the guided portions. Note that the guide portions and the guided portions are not essential to the circuit assembly according to the present disclosure.
(3) Although a plurality of heat conducting sheets 24 are provided as heat conducting members in the above embodiments, and in the first and second embodiments, displacement of the second heat conducting sheet 24b relative to the lower case 60 or 136 is restricted by the displacement restricting portion 118 or 144, and in the third embodiment, displacement of the right second heat conducting sheet 154b relative to the lower case 160 is restricted by the displacement restricting portion 152, the present disclosure is not limited to such configurations. As one example, the displacement of two or more out of a provided plurality of heat conducting members (as one example, heat conducting sheets) relative to the case may be restricted by a displacement restricting portion.

Also, out of the plurality of heat conducting members, members for which displacement relative to the case is not restricted by the displacement restricting portion are not limited to being sandwiched in the vertical direction between a heat transfer portion of a bus bar and the lower case as in the embodiments described above. That is, as one example, a through window that passes through the bottom wall of the lower case in the thickness direction may be provided so that the heat transfer portion is in thermal contact with the heat dissipating body directly through the through window or via a heat conducting member.
(4) Although the locking claw portions 170 of the elastic locking pieces 166 are configured to engage with both ends in the front-rear direction of the second bus bar 18b in the third embodiment described above, the present disclosure is not limited to this configuration. That is, as one example, the locking claw portions of the elastic locking pieces may be configured to engage with a pressing portion of the upper case that presses a bus bar (for example, the second bus bar) from above.
(5) Although a pair of protruding portions 100, 100 are provided on the lower case 60, and a locking portion 102 is provided on each of the protruding portions 100 in the first embodiment described above and a pair of protruding portions 138, 138 are provided on the lower case 136 and a press-fitting protrusion 142 is provided on each protruding portion 138 in the second embodiment described above, the present disclosure is not limited to these configurations. As examples, when a plurality of protruding portions are provided, the configurations of the first embodiment and the second embodiment may be adopted in combination and may be adopted in further combination with the configuration of the third embodiment. In other words, at least two of the configurations described in the first embodiment to the third embodiment can be adopted in combination.
(6) Although the displacement restricting portions 118, 144, 152 are all provided on the lower cases 60, 136, 160 that constitute the case 20 in the embodiments described above, such portions may be provided on the upper case, for example. That is, protruding portions that constitute a displacement restricting portion may be provided on the upper case, and locked portions that fit together with and lock to locking portions on such protruding portions may be provided on the lower case, or a press-fitting holes into which press-fitting protrusions on the protruding portions are press-fitted may be provided on the lower case. Alternatively, elastic locking pieces that constitute a displacement restricting portion may be provided on the upper case and the elastic locking pieces may be configured to engage with edge portions of a bus bar fixed to the lower case. In addition, when assembling the upper case 58, 132, or 156 and the lower case 60, 136, or 160, although the relay 12, the fuse 14, and the bus bars 18 (the first to third bus bars 18a to 18c) are assembled to the upper case 58, 132, or 156 side and the upper case 58, 132, 156 is assembled on the lower case 60, 136, 160 to also fix the relay 12, the fuse 14, and the bus bars 18 (the first to third bus bars 18a to 18c) to the lower case 60, 136, or 160 in the above embodiments, the present disclosure is not limited to this configuration. In other words, the heat-generating components (as examples, relays or fuses) and bus bars may be assembled on the lower case, and the upper case may be assembled to the lower case to also fix the heat-generating components and bus bars to the upper case.
(7) Although the second heat conducting sheet 24b is divided in the left-right direction and provided as left and right second heat conducting sheets 154a, 154b, and the left and right second heat conducting sheets 154a, 154b are disposed so as to be displaced from the positions of the elastic locking pieces 166 in the third embodiment, the present disclosure is not limited to this configuration. That is, in the third embodiment as well, the second heat conducting sheet 24b may be formed in the same shape as in the first and second embodiments. In this case, the flexible pieces of the elastic locking pieces may be configured to restrict displacement of the second heat conducting sheet 24b in the front-rear direction.
(8) Although the heat conducting sheets 24 (the first to third heat conducting sheets 24a to 24c, the left and right second heat conducting sheets 154a, 154b) are described as being fixed in advance to the mounted surfaces 22 (the first to third mounted surfaces 22a to 22c, the left and right second mounted surfaces 164a, 164b) on the bottom wall 90 of the lower case 60, 136, or 160 in the embodiments described above, the present disclosure is not limited to such configurations. That is, as one example, the heat conducting members may be fixed in advance to the lower surface of each heat transfer portion of each bus bar.
(9) Although the displacement of the second heat conducting sheet 24b relative to the case 20 is suppressed in the front-rear direction, the left-right direction (that is, shear directions), and the vertical direction (that is, the tensile direction) through the provision of the displacement restricting portions 118, 144, and 152 in the embodiments described above, the present disclosure is not limited to the above configuration. In the circuit assembly according to the present disclosure, it is sufficient for displacement of the heat conducting member relative to the case to be restricted by a displacement restricting portion in at least one of the front-rear direction, the left-right direction, and vertical direction.

### LIST OF REFERENCE NUMERALS

10 Circuit assembly (first embodiment)
12 Relay (heat generating component)
14 Fuse (heat generating component)
16 Connector portion
16a First connector portion
16b Second connector portion
16c Third connector portion
16d Fourth connector portion
18 Bus bar
18a First bus bar
18b Second bus bar
18c Third bus bar
20 Case
22 Mounted surface
22a First mounted surface
22b Second mounted surface
22c Third mounted surface
24 Heat conducting sheet (heat conducting member)
24a First heat conducting sheet
24b Second heat conducting sheet
24c Third heat conducting sheet
26 Relay body
28 Insulating plate
30 Leg portion
32 Fuse body
34 Bolt insertion hole
36 Bolt
38 Relay connector portion
38a First relay connector portion
38b Second relay connector portion
40 Heat transfer portion
40a First heat transfer portion
40b Second heat transfer portion
40c Third heat transfer portion
42 Left external connector portion
44, 46 Bolt insertion hole
48 Fuse connector portion
50 Through hole
52 Bolt insertion hole
54 Right external connector portion
56 Bolt insertion hole
58 Upper case
60 Lower case
62 Upper bottom wall
64 Upper peripheral wall
66a, 66b Opening
68 Notch
70 Pressing portion
72 Hollow
74 Locked portion
76 Cylindrical portion
78 Engaged claw
80 Inclined surface
82 Positioning rib
84 Guided portion
86 Guided portion body
88 Linking portion
90 Bottom wall
92 Lower peripheral wall
94a, 94b Support portion
96 Upper housing concave portion
96a First upper housing concave portion
96b Second upper housing concave portion
96c Third upper housing concave portion
98 Lower housing concave portion
100 Protruding portion
102 Locking portion
104 Elastic piece
106 Engagement claw
108 Inclined surface
110 Guide portion
112 Guide portion
114 Notched window
116 Through hole
118 Displacement restricting portion
120 Bolt
130 Circuit assembly (second embodiment)
132 Upper case
134 Tubular portion
136 Lower case
138 Protruding portion
140 Press-fitting hole
142 Press-fitting protrusion
144 Displacement restricting portion
150 Circuit assembly (third embodiment)
152 Displacement restricting portion
154a Left second heat conducting sheet
154b Right second heat conducting sheet
156 Upper case
158 Insertion channel
160 Lower case
162a Left second housing concave portion
162b Right second housing concave portion
164a Left second mounted surface
164b Right second mounted surface
166 Elastic locking piece
168 Flexible piece
170 Locking claw portion
172 Inclined surface

1. A circuit assembly comprising:
a heat generating component;
a bus bar connected to a connector portion of the heat generating component;
a case for housing the heat generating component and the bus bar; and
a heat conducting member that is mounted on a mounted surface of the case, is in thermal contact with the case and the bus bar, and is interposed between the case and the bus bar,
wherein the case includes a displacement restricting portion that engages with the heat conducting member and restricts displacement of the heat conducting member.

2. The circuit assembly according to claim 1,
wherein the displacement restricting portion includes a protruding portion that protrudes from the mounted surface of the case,
the heat conducting member includes a first through hole through which the protruding portion is inserted, and
the bus bar includes a second through hole that is placed on the first through hole and through which the protruding portion is inserted and positioned.

3. The circuit assembly according to claim 2,
wherein the case includes a lower case, which includes the mounted surface, and an upper case that is assembled with the lower case with the heat conducting member and the bus bar interposed therebetween,
the upper case includes a locked portion, and
the protruding portion includes a locking portion that is provided on the lower case and fits together with and locks to the locked portion.

4. The circuit assembly according to claim 3,
wherein the upper case includes a positioning rib that positions the bus bar, and
the bus bar is positioned by engagement with the positioning rib, and
the locked portion of the upper case is positioned with respect to the second through hole of the bus bar, the first through hole of the heat conducting member, and also the locking portion that has been passed through the second through hole and the first through hole.

5. The circuit assembly according to either claim 3 or claim 4,
wherein the lower case and the upper case respectively include a guide portion and a guided portion, which are disposed outward of the locking portion and the locked portion, respectively, and
when assembling the upper case to the lower case, the guided portion is guided by the guide portion so that the locked portion of the upper case is positioned on the locking portion of the lower case.

6. The circuit assembly according to claim 2,
wherein the case includes a lower case, which includes the mounted surface, and an upper case that is assembled with the lower case with the heat conducting member and the bus bar interposed therebetween,
the upper case includes a press-fitting hole, and
the protruding portion is provided on the lower case and includes a press-fitting protrusion that is press-fitted into the press-fitting hole.

7. The circuit assembly according to either claim 1 or claim 2,
wherein the displacement restricting portion includes an elastic locking piece that protrudes from a peripheral edge of the mounted surface of the case,
the elastic locking piece includes a flexible piece, which is capable of elastic deformation in an outward direction for the heat conducting member, and a locking claw portion, which is provided at a protruding end portion of the flexible piece, and
the locking claw portion engages with an edge portion of the bus bar that has been placed on the heat conducting member.

8. The circuit assembly according to either claim 3 or claim 4,
wherein the upper case includes a pressing portion that brings the bus bar into contact with the heat conducting member, and
the locked portion is provided on the pressing portion.
